(19) United States
(12) Patent Application Publication
(10) Pub. No.: US 2023/0239626 A1
(43) Pub. Date: Jul. 27, 2023

(54) AUDIO DEVICE APPLICATIONS

(71) Applicant: Meta Platforms Technologies, LLC, Menlo Park, CA (US)

(72) Inventors: Limin Zhou, Redmond, WA (US); Chuming Zhao, Bothell, WA (US); Rex Pinegar Price, Cameron Park, CA (US); Mekell Jiles, Renton, WA (US); Kevin Connor, Seattle, WA (US)

(21) Appl. No.: 18/127,506

(22) Filed: Mar. 28, 2023

Related U.S. Application Data
(60) Provisional application No. 63/325,688, filed on Mar. 31, 2022.
(60) Provisional application No. 63/392,742, filed on Jul. 27, 2022.
(60) Provisional application No. 63/390,890, filed on Jul. 20, 2022.

(51) Int. Cl. H04R 9/04; B81B 7/02; H04R 29/00; H04R 9/06; H05K 1/02

(52) U.S. Cl. CPC H04R 9/046; B81B 7/02; H04R 29/001; H04R 9/06; H04R 9/045; B81B 2201/04; H05K 1/0271

(57) ABSTRACT

A coil assembly for integration into a transducer is presented. The coil assembly may include a metal bobbin assembly, a wire coil, and one or more nonconductive printed circuit board (PCB) stiffeners. A speaker that renders micro noise in an artificial reality environment for improving simulated presence is further presented. The speaker may generate a plurality of micro noises based in part on the determined state of the virtual object. The speaker may spatialize the plurality of micro noises, such that the plurality of micro noises appears to originate from the virtual object. A speaker for speaker diaphragm motion detection using optical MEMS sensors is further presented. Optical MEMS sensors are used to optically monitor displacement of one or more portions of a speaker diaphragm. The speaker may be configured to determine that a speaker diaphragm is in rocking mode and move the speaker diaphragm out of rocking mode.

### CROSS REFERENCE TO RELATED APPLICATIONS

This application claims a priority and benefit to U.S. Provisional Patent Application Ser. No. 63/325,688, Mar. 31, 2022, U.S. Provisional Patent Application Ser. No. 63/392,742, filed Jul. 27, 2022, and U.S. Provisional Patent Application Ser. No. 63/390,890, filed Jul. 20, 2022, each of which is hereby incorporated by reference in its entirety.

### FIELD OF THE INVENTION

The present disclosure relates generally to audio devices, and specifically relates to various audio device applications including, a coil assembly, a speaker for generating micro noises, and a speaker for speaker diaphragm motion detection.

### BACKGROUND

Conventionally, interactions conducted in an artificial reality environment include speech but tend to omit other small background sounds that help cue a listener that a person is present. For example, rustling of clothing, breathing, sounds of movement, etc., generally are not rendered.

Note that speakers used to render audio content in artificial reality environments may be integrated into some form of headset, resulting in a need for a speaker with a relatively small form factor. However, speakers with small form factors can result in manufacturing problems as well as have issues with audio presentation. For example, creating an electrical connection between a (discrete) flat coil to the outside world in a cartilage conduction transducer (or dynamic driver) is difficult due to the required handling of the delicate coil wires and the small connection area. Likewise, in an audio render system, speaker diaphragm motion is a crucial parameter to enable optimal tuning algorithm. Without the motion detection, the render system will either use the static equivalent lumped circuit model parameters from transducer characterization or estimate the parameters based on the current/voltage data from the smart amplifier. The former will not be able to utilize the full range of the speaker system dynamic range since this method assumes the system is perfectly linear. Also, the static parameters are collected based on limited samples and the variation needs to be accounted for. Whereas the latter is an indirect prediction of the speaker motion which has convergence speed and accuracy concerns. But traditional motion measurement techniques, such as contact measurement with accelerometers, are not feasible in audio, especially, in the small form factor products due to the speaker system efficiency is dependent on the moving mass and the accelerometer adds mass to the system and therefore degrades the performance. In addition, there's very limited space for an accelerometer sensor to be attached on diaphragm without interference.

### SUMMARY

Embodiments of the present disclosure relate to a coil assembly that that can be integrated into a transducer device. The coil assembly may include a bobbin assembly, a wire coil, and one or more nonconductive printed circuit board (PCB) stiffeners. The bobbin assembly includes a first and second metal bobbin. The wire coil is placed between the first and second metal bobbin. The metal bobbins each include an electrical tab which is configured to make contact with an end of the wire coil. The electrical tabs provide a reliable electrical contact point to connect to the first end and second end of the wire coil. Nonconductive printed circuit board (PCB) stiffeners are placed on either side of the wire coil, in between the first and second metal bobbin. The nonconductive PCB stiffeners provide support to the metal bobbins and prevent shorting between the first metal bobbin and the second metal bobbin.

Embodiments of the present disclosure further relate to a method for generating micro noises in a virtual environment to improve simulated presence of a virtual object in a virtual environment. Users may use a VR device or AR device, such as a headset, to enter a virtual environment, in which users may be able to interact with virtual objects. Virtual objects may be associated with another user or an artificial intelligence. In some embodiments, virtual objects may be represented by a virtual avatar. Virtual objects include a state, the state indicating whether the virtual avatar is available to interact with the user. The headset may generate a plurality of micro noises based in part on the state of the determined state of the virtual object. Micro noises may be used to communicate information to listeners, such as the state of the virtual object, or the nature of the virtual object (e.g., entity behind the virtual object). In some embodiments, users may assign personalized micro noises to specific virtual objects. In other embodiments, micro noises may be generated based on captured noises from the user. The headset of the user may spatialize and present the plurality of micro noises to the user through a transducer array, such that the plurality of micro noises seems to be coming from the virtual object.

Embodiments of the present disclosure further relate to a speaker that can be integrated into a wearable device. The speaker is configured to perform speaker diaphragm motion detection using optical micro-electromechanical systems (MEMs) sensors. The optical MEMs sensors optically monitor displacement of one or more portions of a speaker diaphragm. The speaker may be integrated into a wearable device (e.g., headset, watch, etc.) of an audio system. The audio system includes one or more speakers, one or more optical MEMS sensors, and a controller. The detected motion of the speaker diaphragm may be used by the audio system to accurately identify system parameter and tune the speaker in real time. Certain algorithms may be tuned (like bass extension or excursion protection) based on a displacement transfer function.

### BRIEF DESCRIPTION OF THE DRAWINGS

FIG. 1A is a perspective view of a headset implemented as an eyewear device, in accordance with one or more embodiments.

FIG. 1B is a perspective view of a headset implemented as a head-mounted display, in accordance with one or more embodiments.

FIG. 2 is a block diagram of an audio system, in accordance with one or more embodiments.

FIG. 3 is a perspective view of a transducer assembly that includes a coil assembly, in accordance with one or more embodiments.

FIG. 4 is a perspective view of the coil assembly of FIG. 4.

FIG. 5 is an exploded view of the coil assembly of FIG. 4.

FIG. 6 is an example virtual environment displayed to a user by a headset, in accordance with one or more embodiments.

FIG. 7 is a flowchart illustrating a process of generating micro noises, in accordance with one or more embodiments.

FIG. 8A is a cross sectional view of an example structure of a speaker with an optical MEMs sensor located on a top surface of a pole piece, in accordance with one or more embodiments.

FIG. 8B is a cross sectional view of an example structure of a speaker with an optical MEMs sensor recessed in a top surface of a pole piece, in accordance with one or more embodiments.

FIG. 8C is a cross sectional view of an example structure of a speaker with a plurality of optical MEMs sensor recessed into a top surface of a pole piece, in accordance with one or more embodiments.

FIG. 8D is a cross sectional view of an example structure of a speaker with an optical MEMs sensor recessed in a top surface of a pole piece, in accordance with one or more embodiments.

FIG. 9 is cross sectional view of an example structure of a speaker with a plurality of optical MEMs sensors positioned on a frame of a wearable device, in accordance with one or more embodiments.

FIG. 10 is a cross sectional view of an example structure of an optical MEMs sensor, in accordance with one or more embodiments.

FIG. 11 is a flowchart illustrating a process of tuning the speaker diaphragm to move out of rocking mode, in accordance with one or more embodiments.

FIG. 12 depicts a block diagram of a system that includes a wearable device (e.g., headset), in accordance with one or more embodiments.

The figures depict various embodiments for purposes of illustration only. One skilled in the art will readily recognize from the following discussion that alternative embodiments of the structures and methods illustrated herein may be employed without departing from the principles described herein.

### DETAILED DESCRIPTION

Embodiments of the present disclosure relate to various audio device applications. A coil assembly for a transducer, which can be integrated into a speaker is presented in this disclosure. Connecting a flat coil with an external environment in a cartilage conduction transducer is a challenge due to delicate coil wires and small connection area. To mitigate these challenges, a conductive bobbin assembly can be used in conjunction with the voice coil. The coil assembly includes a bobbin assembly, a wire coil, and one or more nonconductive stiffeners. The bobbin assembly includes a first and second metal bobbin, each metal bobbin having a first and second face. The wire coil is placed between the first and second metal bobbin, the wire coil facing the first face of the first metal bobbin and the first face of the second metal bobbin. The wire coil includes a first end and a second end. The first metal bobbin includes a first electrical tab which makes contact with the first end of the wire coil. The second metal bobbin includes a second electrical tab which makes contact with the second end of the wire coil. The electrical tabs provide a reliable electrical contact point to connect to the first end and second end of the wire coil. Nonconductive printed circuit board (PCB) stiffeners are placed on either side of the wire coil, in between the first and second metal bobbin. The nonconductive PCB stiffeners provide support to the metal bobbins and prevent shorting between the first metal bobbin and the second metal bobbin.

Some embodiments of the present disclosure are directed at a method for generating micro noises for improving simulated presence of a virtual object in a virtual environment. Conventionally, an AR device or a VR device of a user filters out background noise from the user and only transmits the user's speech to a server or to other VR devices or AR devices for presentation to other users. However, this implementation lacks elements that create a more realistic experience in the virtual environment, such as micro noises. To introduce an element of realism to the virtual experience, the headset of the user may generate micro noises that may seem to be coming from the virtual object. In some embodiments, virtual objects may be represented by a virtual avatar. In some embodiments, the micro noises reflect movement (e.g., body movement) of the virtual avatar and is delivered to other users through their VR device or AR device. This allows the virtual object to communicate a state to other users in the virtual environment. For example, a virtual avatar associated with a user may be present in the virtual environment, but the user is performing another action. To indicate the user's away state, the virtual avatar may generate a micro noise to communicate their state to other users. Micro noises may also be used to communicate other types of information, such as the nature of the virtual object.

Some embodiments of the present disclosure are directed at a speaker that can be integrated into a wearable device. The speaker is configured to perform speaker diaphragm motion detection using optical MEMs sensors. The speaker uses audio render algorithms, which use the movement of the speaker diaphragm, to update speaker algorithm parameters in real time for better audio performance. Conventional motion measurement techniques, such as contact measurement with an accelerometer positioned on the speaker diaphragm, are not feasible in small form factor audio devices. This challenge may be overcome by using optical MEMS sensors, which use light to determine the movement of the speaker diaphragm. These optical MEMS sensors may be encased inside (e.g., under the diaphragm) or outside the speaker (e.g., over the diaphragm). If multiple optical MEMS sensors are used, the audio controller may be configured to detect rocking mode of the speaker and mitigate the impacts of rocking mode on the speaker.

Embodiments of the invention may include or be implemented in conjunction with an artificial reality system. Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to create content in an artificial reality and/or are otherwise used in an artificial reality. The artificial reality system that provides the artificial reality content may be implemented on various platforms, including a wearable device (e.g., headset) connected to a host computer system, a standalone wearable device (e.g., headset), a mobile device or computing system, or any other hardware platform capable of providing artificial reality content to one or more viewers.

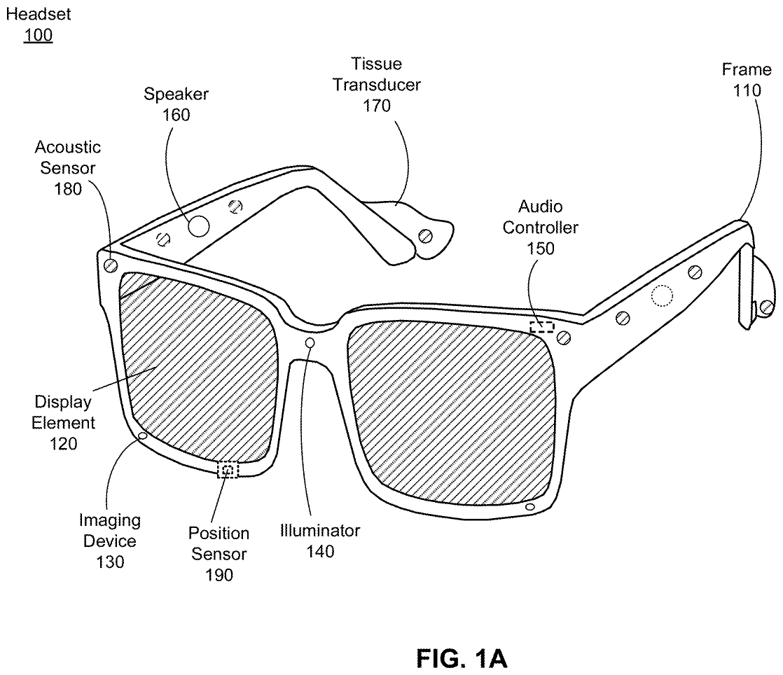

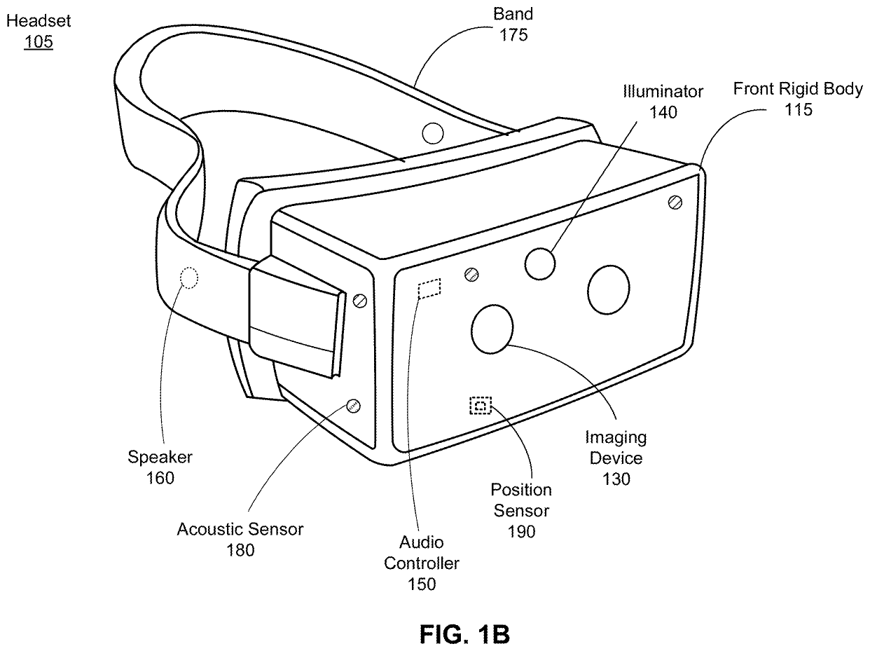

FIG. 1A is a perspective view of a headset 100 implemented as an eyewear device, in accordance with one or more embodiments. In some embodiments, the eyewear device is a near eye display (NED). In general, the headset 100 may be worn on the face of a user such that content (e.g., media content) is presented using a display assembly and/or an audio system. However, the headset 100 may also be used such that media content is presented to a user in a different manner. Examples of media content presented by the headset 100 include one or more images, video, audio, or some combination thereof. The headset 100 includes a frame, and may include, among other components, a display assembly including one or more display elements 120, a depth camera assembly (DCA), an audio system, and a position sensor 190. While FIG. 1A illustrates the components of the headset 100 in example locations on the headset 100, the components may be located elsewhere on the headset 100, on a peripheral device paired with the headset 100, or some combination thereof. Similarly, there may be more or fewer components on the headset 100 than what is shown in FIG. 1A.

The frame 110 holds the other components of the headset 100. The frame 110 includes a front part that holds the one or more display elements 120 and end pieces (e.g., temples) to attach to a head of the user. The front part of the frame 110 bridges the top of a nose of the user. The length of the end pieces may be adjustable (e.g., adjustable temple length) to fit different users. The end pieces may also include a portion that curls behind the ear of the user (e.g., temple tip, ear piece).

The one or more display elements 120 provide light to a user wearing the headset 100. As illustrated the headset includes a display element 120 for each eye of a user. In some embodiments, a display element 120 generates image light that is provided to an eyebox of the headset 100. The eyebox is a location in space that an eye of user occupies while wearing the headset 100. For example, a display element 120 may be a waveguide display. A waveguide display includes a light source (e.g., a two-dimensional source, one or more line sources, one or more point sources, etc.) and one or more waveguides. Light from the light source is in-coupled into the one or more waveguides which outputs the light in a manner such that there is pupil replication in an eyebox of the headset 100. In-coupling and/or outcoupling of light from the one or more waveguides may be done using one or more diffraction gratings. In some embodiments, the waveguide display includes a scanning element (e.g., waveguide, mirror, etc.) that scans light from the light source as it is in-coupled into the one or more waveguides. Note that in some embodiments, one or both of the display elements 120 are opaque and do not transmit light from a local area around the headset 100. The local area is the area surrounding the headset 100. For example, the local area may be a room that a user wearing the headset 100 is inside, or the user wearing the headset 100 may be outside and the local area is an outside area. In this context, the headset 100 generates VR content. Alternatively, in some embodiments, one or both of the display elements 120 are at least partially transparent, such that light from the local area may be combined with light from the one or more display elements to produce AR and/or MR content.

In some embodiments, a display element 120 does not generate image light, and instead is a lens that transmits light from the local area to the eyebox. For example, one or both of the display elements 120 may be a lens without correction (non-prescription) or a prescription lens (e.g., single vision, bifocal and trifocal, or progressive) to help correct for defects in a user's eyesight. In some embodiments, the display element 120 may be polarized and/or tinted to protect the user's eyes from the sun.

In some embodiments, the display element 120 may include an additional optics block (not shown). The optics block may include one or more optical elements (e.g., lens, Fresnel lens, etc.) that direct light from the display element 120 to the eyebox. The optics block may, e.g., correct for aberrations in some or all of the image content, magnify some or all of the image, or some combination thereof.

The DCA determines depth information for a portion of a local area surrounding the headset 100. The DCA includes one or more imaging devices 130 and a DCA controller (not shown in FIG. 1A), and may also include an illuminator 140. In some embodiments, the illuminator 140 illuminates a portion of the local area with light. The light may be, e.g., structured light (e.g., dot pattern, bars, etc.) in the infrared (IR), IR flash for time-of-flight, etc. In some embodiments, the one or more imaging devices 130 capture images of the portion of the local area that include the light from the illuminator 140. As illustrated, FIG. 1A shows a single illuminator 140 and two imaging devices 130. In alternate embodiments, there is no illuminator 140 and at least two imaging devices 130.

The DCA controller computes depth information for the portion of the local area using the captured images and one or more depth determination techniques. The depth determination technique may be, e.g., direct time-of-flight (ToF) depth sensing, indirect ToF depth sensing, structured light, passive stereo analysis, active stereo analysis (uses texture added to the scene by light from the illuminator 140), some other technique to determine depth of a scene, or some combination thereof.

The audio system provides audio content. The audio system includes a transducer array, a sensor array, and an audio controller 150. However, in other embodiments, the audio system may include different and/or additional components. Similarly, in some cases, functionality described with reference to the components of the audio system can be distributed among the components in a different manner than is described here. For example, some or all of the functions of the controller may be performed by a remote server.

The transducer array presents sound to user. The transducer array includes a plurality of transducers. A transducer may be a speaker 160 or a tissue transducer 170 (e.g., a bone conduction transducer or a cartilage conduction transducer). In some embodiments, the transducers may be implemented with a coil assembly, configured to act as an electrical pathway between a voice coil and an electrical source. The coil assembly may include a conductive bobbin assembly, a voice coil, and one or more nonconductive PCB stiffeners.

In other embodiments, a transducer implemented as a speaker may include one or more optical MEMS sensors to perform speaker diaphragm motion detection. The headset 100 may use the speaker diaphragm motion to enable an optimal tuning algorithm for better audio performance.

Although the speakers 160 are shown exterior to the frame 110, the speakers 160 may be enclosed in the frame 110. In some embodiments, instead of individual speakers for each ear, the headset 100 includes a speaker array comprising multiple speakers integrated into the frame 110 to improve directionality of presented audio content. The tissue transducer 170 couples to the head of the user and directly vibrates tissue (e.g., bone or cartilage) of the user to generate sound. The number and/or locations of transducers may be different from what is shown in FIG. 1A.

The sensor array detects sounds within the local area of the headset 100. The sensor array includes a plurality of acoustic sensors 180. An acoustic sensor 180 captures sounds emitted from one or more sound sources in the local area (e.g., a room). Each acoustic sensor is configured to detect sound and convert the detected sound into an electronic format (analog or digital). The acoustic sensors 180 may be acoustic wave sensors, microphones, sound transducers, or similar sensors that are suitable for detecting sounds.

In some embodiments, one or more acoustic sensors 180 may be placed in an ear canal of each ear (e.g., acting as binaural microphones). In some embodiments, the acoustic sensors 180 may be placed on an exterior surface of the headset 100, placed on an interior surface of the headset 100, separate from the headset 100 (e.g., part of some other device), or some combination thereof. The number and/or locations of acoustic sensors 180 may be different from what is shown in FIG. 1A. For example, the number of acoustic detection locations may be increased to increase the amount of audio information collected and the sensitivity and/or accuracy of the information. The acoustic detection locations may be oriented such that the microphone is able to detect sounds in a wide range of directions surrounding the user wearing the headset 100.

The audio controller 150 processes information from the sensor array that describes sounds detected by the sensor array. The audio controller 150 may comprise a processor and a computer-readable storage medium. The audio controller 150 may be configured to generate direction of arrival (DOA) estimates, generate acoustic transfer functions (e.g., array transfer functions and/or head-related transfer functions), track the location of sound sources, form beams in the direction of sound sources, classify sound sources, generate sound filters for the speakers 160, or some combination thereof. The audio controller 150 may be configured to generate micro noises to improve a simulated presence of a virtual object in a virtual environment. The micro noises may be generated to communicate to users, a state of the virtual object, or a nature of the virtual object.

The position sensor 190 generates one or more measurement signals in response to motion of the headset 100. The position sensor 190 may be located on a portion of the frame 110 of the headset 100. The position sensor 190 may include an inertial measurement unit (IMU). Examples of position sensor 190 include: one or more accelerometers, one or more gyroscopes, one or more magnetometers, another suitable type of sensor that detects motion, a type of sensor used for error correction of the IMU, or some combination thereof. The position sensor 190 may be located external to the IMU, internal to the IMU, or some combination thereof.

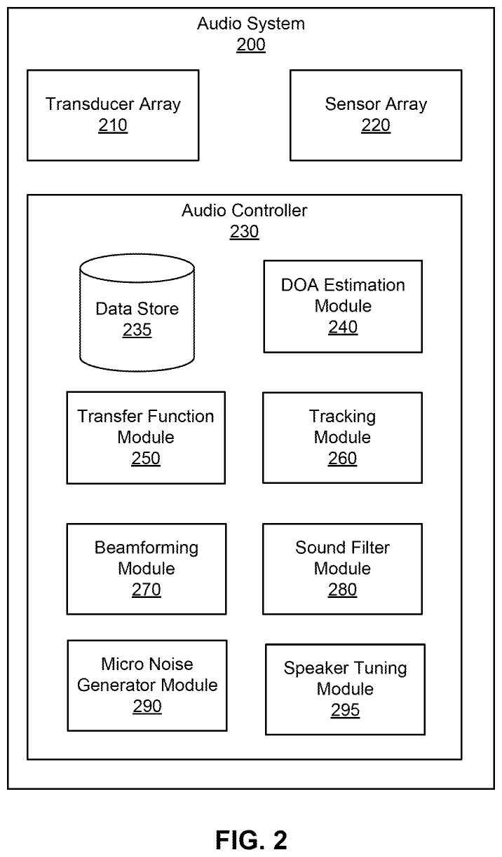

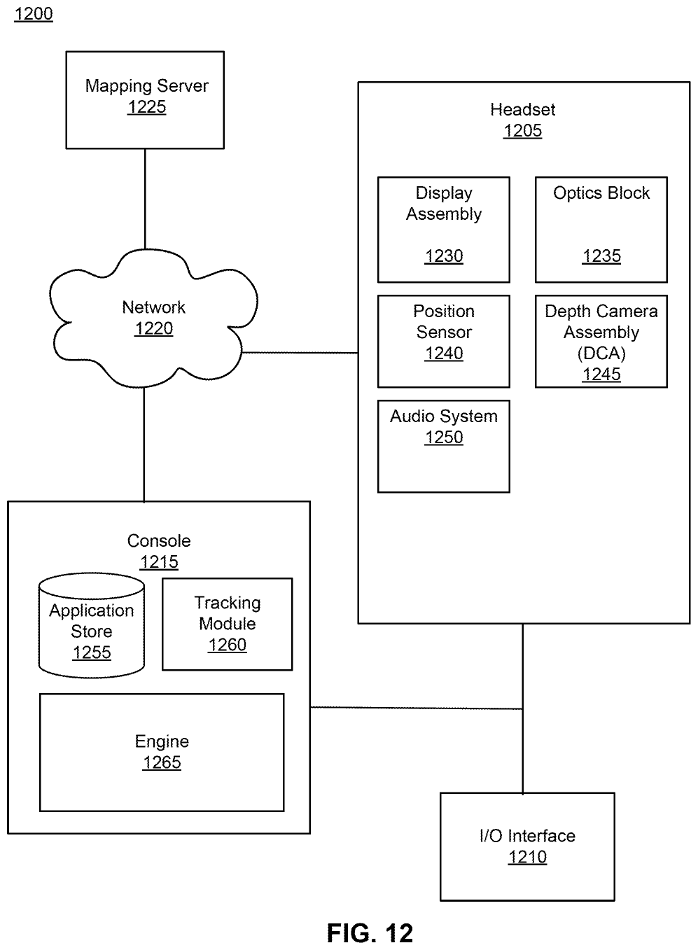

In some embodiments, the headset 100 may provide for simultaneous localization and mapping (SLAM) for a position of the headset 100 and updating of a model of the local area. For example, the headset 100 may include a passive camera assembly (PCA) that generates color image data. The PCA may include one or more RGB cameras that capture images of some or all of the local area. In some embodiments, some or all of the imaging devices 130 of the DCA may also function as the PCA. The images captured by the PCA and the depth information determined by the DCA may be used to determine parameters of the local area, generate a model of the local area, update a model of the local area, or some combination thereof. Furthermore, the position sensor 190 tracks the position (e.g., location and pose) of the headset 100 within the room. Additional details regarding the components of the headset 100 are discussed below in connection with FIG. 2 and FIG. 12.

FIG. 1B is a perspective view of a headset 105 implemented as a HMD, in accordance with one or more embodiments. In embodiments that describe an AR system and/or a MR system, portions of a front side of the HMD are at least partially transparent in the visible band (˜380 nm to 750 nm), and portions of the HMD that are between the front side of the HMD and an eye of the user are at least partially transparent (e.g., a partially transparent electronic display). The HMD includes a front rigid body 115 and a band 175. The headset 105 includes many of the same components described above with reference to FIG. 1A, but modified to integrate with the HMD form factor. For example, the HMD includes a display assembly, a DCA, an audio system, and a position sensor 190. FIG. 1B shows the illuminator 140, a plurality of the speakers 160, a plurality of the imaging devices 130, a plurality of acoustic sensors 180, and the position sensor 190. The speakers 160 may be located in various locations, such as coupled to the band 175 (as shown), coupled to front rigid body 115, or may be configured to be inserted within the ear canal of a user.

FIG. 2 is a block diagram of an audio system 200, in accordance with one or more embodiments. The audio system in FIG. 1A or FIG. 1B may be an embodiment of the audio system 200. The audio system 200 generates one or more acoustic transfer functions for a user. The audio system 200 may then use the one or more acoustic transfer functions to generate audio content for the user. In the embodiment of FIG. 2, the audio system 200 includes a transducer array 210, a sensor array 220, and an audio controller 230. Some embodiments of the audio system 200 have different components than those described here. Similarly, in some cases, functions can be distributed among the components in a different manner than is described here.

The transducer array 210 is configured to present audio content. The transducer array 210 includes a plurality of transducers. A transducer is a device that provides audio content. A transducer may be, e.g., a speaker (e.g., the speaker 160), a tissue transducer (e.g., the tissue transducer 170), some other device that provides audio content, or some combination thereof. A tissue transducer may be configured to function as a bone conduction transducer or a cartilage conduction transducer. The transducer array 210 may present audio content via air conduction (e.g., via one or more speakers), via bone conduction (via one or more bone conduction transducer), via cartilage conduction audio system (via one or more cartilage conduction transducers), or some combination thereof. In some embodiments, the transducer array 210 may include one or more transducers to cover different parts of a frequency range. For example, a piezoelectric transducer may be used to cover a first part of a frequency range and a moving coil transducer may be used to cover a second part of a frequency range.

The bone conduction transducers generate acoustic pressure waves by vibrating bone/tissue in the user's head. A bone conduction transducer may be coupled to a portion of a headset, and may be configured to be behind the auricle coupled to a portion of the user's skull. The bone conduction transducer receives vibration instructions from the audio controller 230, and vibrates a portion of the user's skull based on the received instructions. The vibrations from the bone conduction transducer generate a tissue-borne acoustic pressure wave that propagates toward the user's cochlea, bypassing the eardrum.

The cartilage conduction transducers generate acoustic pressure waves by vibrating one or more portions of the auricular cartilage of the ears of the user. A cartilage conduction transducer may be coupled to a portion of a headset, and may be configured to be coupled to one or more portions of the auricular cartilage of the ear. For example, the cartilage conduction transducer may couple to the back of an auricle of the ear of the user. The cartilage conduction transducer may be located anywhere along the auricular cartilage around the outer ear (e.g., the pinna, the tragus, some other portion of the auricular cartilage, or some combination thereof). Vibrating the one or more portions of auricular cartilage may generate: airborne acoustic pressure waves outside the ear canal; tissue born acoustic pressure waves that cause some portions of the ear canal to vibrate thereby generating an airborne acoustic pressure wave within the ear canal; or some combination thereof. The generated airborne acoustic pressure waves propagate down the ear canal toward the ear drum.

The transducer array 210 generates audio content in accordance with instructions from the audio controller 230. In some embodiments, the audio content is spatialized. Spatialized audio content is audio content that appears to originate from a particular direction and/or target region (e.g., an object in the local area and/or a virtual object). For example, spatialized audio content can make it appear that sound is originating from a virtual singer across a room from a user of the audio system 200. The transducer array 210 may be coupled to a wearable device (e.g., the headset 100 or the headset 105). In alternate embodiments, the transducer array 210 may be a plurality of speakers that are separate from the wearable device (e.g., coupled to an external console).

In some embodiments, the transducers may be implemented with a coil assembly. The coil assembly including a conductive bobbin assembly, a voice coil, and one or more nonconductive PCB stiffeners. The voice coil assembly 820 acts as an electrical pathway between the voice coil and an electrical source. The metal bobbin assembly is comprised of a first and second metal bobbin. The metal bobbin assembly includes electrical tabs which are configured to provide reliable electrical contact points to connect to the voice coil.

In other embodiments, a speaker may include one or more optical MEMS sensors to perform speaker diaphragm motion detection. The optical MEMs sensor may include one or more light sources (e.g., vertical cavity surface emitting lasers (VCSELs)), one or more sensors (e.g., photodiodes), and may also include one or more diffraction gratings. The VCSEL emits light beams through the diffraction grating and reaches to the moving diaphragm. The light beams are reflected and diffracted depending on the motion and received by the photodiodes resulting in photocurrent and converted to electrical voltage. The one or more optical MEMS sensors may be positioned in a variety of locations relative to the speaker diaphragm. The locations may be within the speaker(s), external to the speaker(s), or some combination thereof. For example, in some embodiments, one or more optical MEMS sensors may be positioned on a speaker pole piece to monitor a back side of the speaker diaphragm.

The sensor array 220 detects sounds within a local area surrounding the sensor array 220. The sensor array 220 may include a plurality of acoustic sensors that each detect air pressure variations of a sound wave and convert the detected sounds into an electronic format (analog or digital). The plurality of acoustic sensors may be positioned on a headset (e.g., headset 100 and/or the headset 105), on a user (e.g., in an ear canal of the user), on a neckband, or some combination thereof. An acoustic sensor may be, e.g., a microphone, a vibration sensor, an accelerometer, or any combination thereof. In some embodiments, the sensor array 220 is configured to monitor the audio content generated by the transducer array 210 using at least some of the plurality of acoustic sensors. Increasing the number of sensors may improve the accuracy of information (e.g., directionality) describing a sound field produced by the transducer array 210 and/or sound from the local area.

The audio controller 230 controls operation of the audio system 200. In the embodiment of FIG. 2, the audio controller 230 includes a data store 235, a DOA estimation module 240, a transfer function module 250, a tracking module 260, a beamforming module 270, and a sound filter module 280. The audio controller 230 may be located inside a headset, in some embodiments. Some embodiments of the audio controller 230 have different components than those described here. Similarly, functions can be distributed among the components in different manners than described here. For example, some functions of the controller may be performed external to the headset. The user may opt in to allow the audio controller 230 to transmit data captured by the headset to systems external to the headset, and the user may select privacy settings controlling access to any such data.

The data store 235 stores data for use by the audio system 200. Data in the data store 235 may include sounds recorded in the local area of the audio system 200, audio content, head-related transfer functions (HRTFs), transfer functions for one or more sensors, array transfer functions (ATFs) for one or more of the acoustic sensors, sound source locations, virtual model of local area, direction of arrival estimates, sound filters, and other data relevant for use by the audio system 200, or any combination thereof. The data store 235 may store micro noises or captured body noises from the user. The data store 235 may also store speaker tuning algorithms.

The user may opt-in to allow the data store 235 to record data captured by the audio system 200. In some embodiments, the audio system 200 may employ always on recording, in which the audio system 200 records all sounds captured by the audio system 200 in order to improve the experience for the user. The user may opt in or opt out to allow or prevent the audio system 200 from recording, storing, or transmitting the recorded data to other entities.

The DOA estimation module 240 is configured to localize sound sources in the local area based in part on information from the sensor array 220. Localization is a process of determining where sound sources are located relative to the user of the audio system 200. The DOA estimation module 240 performs a DOA analysis to localize one or more sound sources within the local area. The DOA analysis may include analyzing the intensity, spectra, and/or arrival time of each sound at the sensor array 220 to determine the direction from which the sounds originated. In some cases, the DOA analysis may include any suitable algorithm for analyzing a surrounding acoustic environment in which the audio system 200 is located.

For example, the DOA analysis may be designed to receive input signals from the sensor array 220 and apply digital signal processing algorithms to the input signals to estimate a direction of arrival. These algorithms may include, for example, delay and sum algorithms where the input signal is sampled, and the resulting weighted and delayed versions of the sampled signal are averaged together to determine a DOA. A least mean squared (LMS) algorithm may also be implemented to create an adaptive filter. This adaptive filter may then be used to identify differences in signal intensity, for example, or differences in time of arrival. These differences may then be used to estimate the DOA. In another embodiment, the DOA may be determined by converting the input signals into the frequency domain and selecting specific bins within the time-frequency (TF) domain to process. Each selected TF bin may be processed to determine whether that bin includes a portion of the audio spectrum with a direct path audio signal. Those bins having a portion of the direct-path signal may then be analyzed to identify the angle at which the sensor array 220 received the direct-path audio signal. The determined angle may then be used to identify the DOA for the received input signal. Other algorithms not listed above may also be used alone or in combination with the above algorithms to determine DOA.

In some embodiments, the DOA estimation module 240 may also determine the DOA with respect to an absolute position of the audio system 200 within the local area. The position of the sensor array 220 may be received from an external system (e.g., some other component of a headset, an artificial reality console, a mapping server, a position sensor (e.g., the position sensor 190), etc.). The external system may create a virtual model of the local area, in which the local area and the position of the audio system 200 are mapped. The received position information may include a location and/or an orientation of some or all of the audio system 200 (e.g., of the sensor array 220). The DOA estimation module 240 may update the estimated DOA based on the received position information.

The transfer function module 250 is configured to generate one or more acoustic transfer functions. Generally, a transfer function is a mathematical function giving a corresponding output value for each possible input value. Based on parameters of the detected sounds, the transfer function module 250 generates one or more acoustic transfer functions associated with the audio system. The acoustic transfer functions may be array transfer functions (ATFs), head-related transfer functions (HRTFs), other types of acoustic transfer functions, or some combination thereof. An ATF characterizes how the microphone receives a sound from a point in space.

An ATF includes a number of transfer functions that characterize a relationship between the sound source and the corresponding sound received by the acoustic sensors in the sensor array 220. Accordingly, for a sound source there is a corresponding transfer function for each of the acoustic sensors in the sensor array 220. And collectively the set of transfer functions is referred to as an ATF. Accordingly, for each sound source there is a corresponding ATF. Note that the sound source may be, e.g., someone or something generating sound in the local area, the user, or one or more transducers of the transducer array 210. The ATF for a particular sound source location relative to the sensor array 220 may differ from user to user due to a person's anatomy (e.g., ear shape, shoulders, etc.) that affects the sound as it travels to the person's ears. Accordingly, the ATFs of the sensor array 220 are personalized for each user of the audio system 200.

In some embodiments, the transfer function module 250 determines one or more HRTFs for a user of the audio system 200. The HRTF characterizes how an ear receives a sound from a point in space. The HRTF for a particular source location relative to a person is unique to each ear of the person (and is unique to the person) due to the person's anatomy (e.g., ear shape, shoulders, etc.) that affects the sound as it travels to the person's ears. In some embodiments, the transfer function module 250 may determine HRTFs for the user using a calibration process. In some embodiments, the transfer function module 250 may provide information about the user to a remote system. The user may adjust privacy settings to allow or prevent the transfer function module 250 from providing the information about the user to any remote systems. The remote system determines a set of HRTFs that are customized to the user using, e.g., machine learning, and provides the customized set of HRTFs to the audio system 200.

The tracking module 260 is configured to track locations of one or more sound sources. The tracking module 260 may compare current DOA estimates and compare them with a stored history of previous DOA estimates. In some embodiments, the audio system 200 may recalculate DOA estimates on a periodic schedule, such as once per second, or once per millisecond. The tracking module may compare the current DOA estimates with previous DOA estimates, and in response to a change in a DOA estimate for a sound source, the tracking module 260 may determine that the sound source moved. In some embodiments, the tracking module 260 may detect a change in location based on visual information received from the headset or some other external source. The tracking module 260 may track the movement of one or more sound sources over time. The tracking module 260 may store values for a number of sound sources and a location of each sound source at each point in time. In response to a change in a value of the number or locations of the sound sources, the tracking module 260 may determine that a sound source moved. The tracking module 260 may calculate an estimate of the localization variance. The localization variance may be used as a confidence level for each determination of a change in movement.

The beamforming module 270 is configured to process one or more ATFs to selectively emphasize sounds from sound sources within a certain area while de-emphasizing sounds from other areas. In analyzing sounds detected by the sensor array 220, the beamforming module 270 may combine information from different acoustic sensors to emphasize sound associated from a particular region of the local area while deemphasizing sound that is from outside of the region. The beamforming module 270 may isolate an audio signal associated with sound from a particular sound source from other sound sources in the local area based on, e.g., different DOA estimates from the DOA estimation module 240 and the tracking module 260. The beamforming module 270 may thus selectively analyze discrete sound sources in the local area. In some embodiments, the beamforming module 270 may enhance a signal from a sound source. For example, the beamforming module 270 may apply sound filters which eliminate signals above, below, or between certain frequencies. Signal enhancement acts to enhance sounds associated with a given identified sound source relative to other sounds detected by the sensor array 220.

The sound filter module 280 determines sound filters for the transducer array 210. In some embodiments, the sound filters cause the audio content to be spatialized, such that the audio content appears to originate from a target region. The sound filter module 280 may use HRTFs and/or acoustic parameters to generate the sound filters. The acoustic parameters describe acoustic properties of the local area. The acoustic parameters may include, e.g., a reverberation time, a reverberation level, a room impulse response, etc. In some embodiments, the sound filter module 280 calculates one or more of the acoustic parameters. In some embodiments, the sound filter module 280 requests the acoustic parameters from a mapping server (e.g., as described below with regard to FIG. 12).

The sound filter module 280 provides the sound filters to the transducer array 210. In some embodiments, the sound filters may cause positive or negative amplification of sounds as a function of frequency.

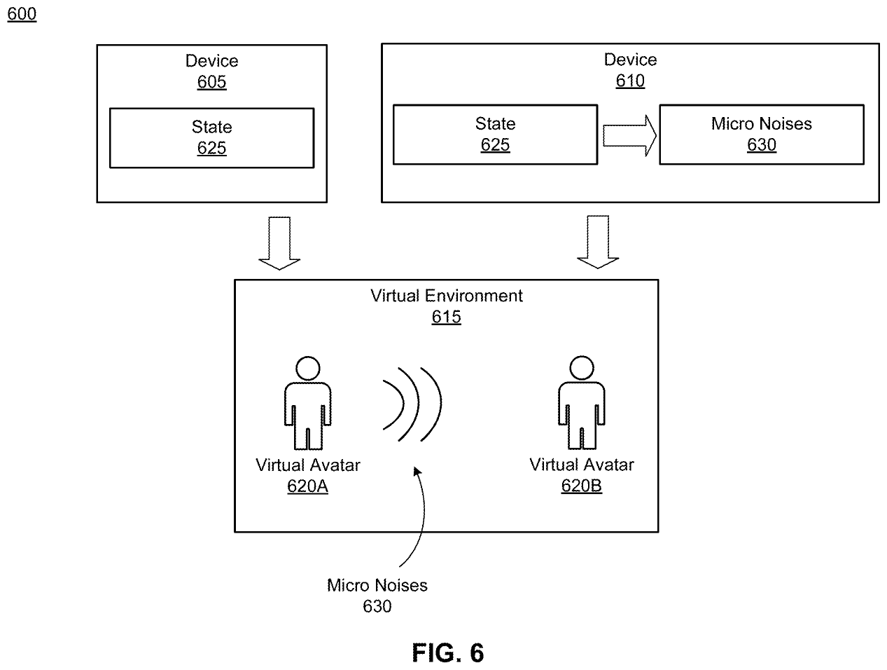

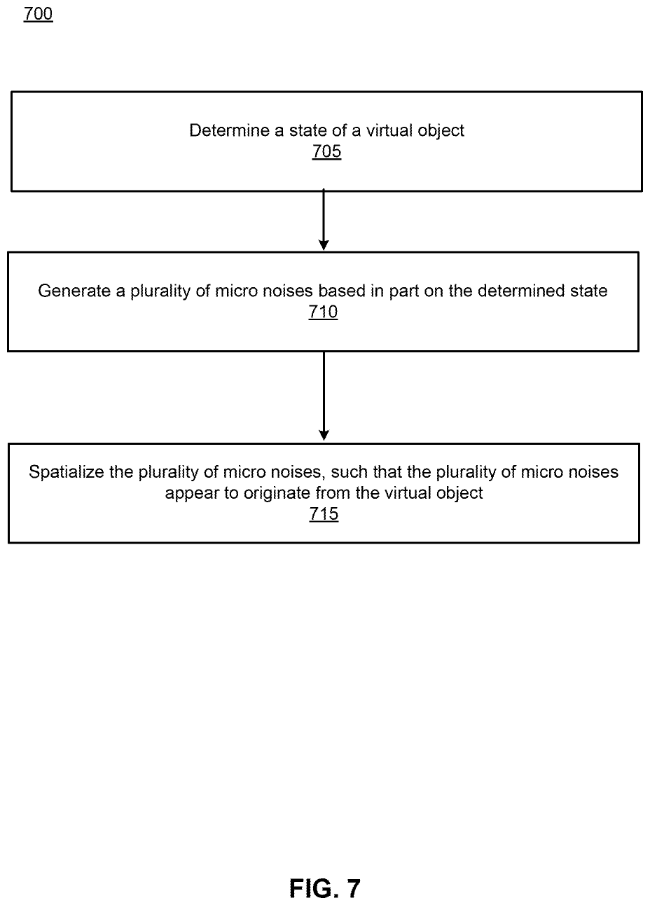

The audio controller 230 also includes a micro noise generator module 290 that identifies the state of a virtual object, and generates micro noises based in part on the determined state of the virtual object. As further described below in conjunction with FIGS. 6 and 7, the micro noise generator module 290 may determine the state of a virtual object present in a local area of a user in a virtual environment. Based on the state of the virtual object, the micro noise generator module 290 generates a plurality of micro noises to be presented to the user. In some embodiments, a library of pre-generated micro noises may be stored in the data store 235. For example, pre-generated micro noises may include generic breathing noises, clothing rustling noises, or noises of feet shuffling on the ground. The micro noise generator module 290 may map each of the pre-generated micro noises to a state of a virtual object. In some embodiments, the micro noise generator module 290 also map micro noises to a nature of a virtual object, or to an action of a virtual object. For example, the micro noise generator module 290 may categorize virtual objects into categories such as unfamiliar virtual objects, familiar virtual objects, user-controlled virtual objects, or an AI-controlled virtual object. The micro noise generator module 290 may retrieve from the data store 235, the pre-generated micro noise for spatialization and presentation to the user.

In some embodiments, the micro noise generator module 290 may use machine learning (ML) models to generate new micro noises based on the state of the virtual object for spatialization and presentation to the user. In other embodiments, the micro noise generator module 290 may also use ML models to generate new micro noises based on the nature of the virtual object, or the action performed by the virtual object. Example machine learning models include regression models, support vector machines, naïve bayes, decision trees, k nearest neighbors, random forest, boosting algorithms, k-means, and hierarchical clustering. The machine learning models may also include neural networks, such as perceptrons, multi-layer perceptrons, convolutional neural networks (CNNs), recurrent neural networks (RNNs), sequence-to-sequence models, generative adversarial networks, automatic speech recognition (ASR) models, or transformers. The micro noise generator module 290 may store newly generated micro noises in the data store 235.

In some embodiments, the micro noise generator module 290 may instruct the sensor array 220 to capture body noises (e.g., breathing sounds, rustling, clothing moving) from the user of the headset. The micro noise generator module 290 may use as input, the captured body noises from the user to the ML models to generate a plurality of micro noises that is unique to the user. In other embodiments, a user may assign a pre-generated or newly generated micro noise to a particular virtual object. For example, a user may select and assign a micro noise to a virtual object associated with a family member.

The micro noise generator module 290 may provide the plurality of micro noises to the sound filter module 280. The sound filter module 280 may apply sound filters to the micro noises to spatialize the plurality of micro noises for presentation to the user, such that the plurality of micro noises appears to originate from the virtual object. The spatialized micro noises may be presented to the user through the transducer array 210.

The audio controller 230 also includes a speaker tuning module 295 that is configured to determine if the speaker diaphragm is in rocking mode and to tune speaker algorithm parameters to move the diaphragm out of rocking mode. The speaker tuning module 295 may use signals received from a speaker which includes more than one optical MEMS sensors to determine whether the diaphragm is in rocking mode. The speaker tuning module 295 may instruct the more than one optical MEMS sensors to emit light beams through the diffraction grating towards the moving diaphragm. The speaker tuning module 295 may use the reflected and diffracted light beams detected by the photodiodes to determine if the diaphragm is in rocking mode. The more than one optical MEMS sensors enable multiple point motion detection to detect that the speaker diaphragm is in rocking mode. The speaker tuning module 295 may use a depth determination technique like, e.g., direct time-of-flight (dTOF), indirect TOF (iTOF), etc., to calculate displacement of the monitored portions of the diaphragm. The speaker tuning module 295 may, in response to determining that the speaker is in or close to being in rocking mode, the speaker tuning module 295 may modify drive algorithm parameters for the diaphragm to move the diaphragm out of the rocking mode. Algorithms may include bass extension or excursion protection, based on a displacement transfer function. The speaker tuning module 295 may provide the adjusted drive algorithm parameters to the transducer array 210 to modify the transducer output.

Other embodiments of the audio controller may have more or fewer components than described.

### Coil Assembly for a Speaker

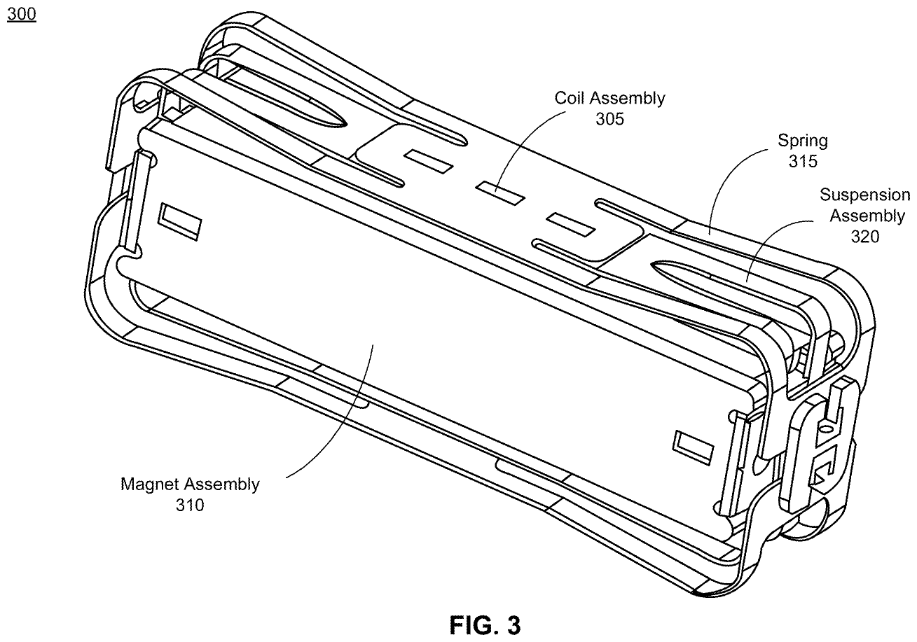

Some embodiments of the present disclosure are directed to a coil assembly for a transducer assembly. FIG. 3 is a perspective view of a transducer assembly 300 that includes a coil assembly 305, in accordance with one or more embodiments. The transducer assembly 300 may be implemented in wearable devices which includes, head-mounted devices such as artificial reality headsets and smart glasses. The transducer assembly 300 is an embodiment of the transducer described above with regard to FIGS. 1A-3. For example, the transducer assembly 300 may be implemented as a tissue transducer 170 or a speaker. The transducer assembly 300 includes the coil assembly 305, a magnet assembly 310, a spring 315, and suspension assembly 320. There may be more or fewer components in the coil assembly 305 than what is shown in FIG. 3.

The coil assembly 305 includes a voice coil which is configured to generate a magnetic field when current is applied to the voice coil. The coil assembly 305 may be coupled to the spring 315, configured to allow movement of the coil assembly 305.

The magnet assembly 310 may include two magnets, each magnet positioned on either side of the coil assembly 305. The magnet assembly 310 may be coupled to the suspension assembly 320. The suspension assembly 320 configured to allow movement of the magnet assembly 310 relative to the coil assembly 305. In addition, a membrane (not pictured) or a contact pad (not pictured) may be positioned on top of the spring 315 and is configured to vibrate and generate audio content. The magnetic field of the voice coil interacts with the magnetic field of the magnet assembly 310, generating a magnetic force causing the coil assembly 305 and the magnet assembly 310 to move in opposite directions. The movement of the coil assembly 305 causes the membrane to vibrate to generate sound. The transducer assembly 300 may be configured to mitigate the vibrations generated by the membrane and prevent the generated vibrations from spreading to the rest of the wearable device.

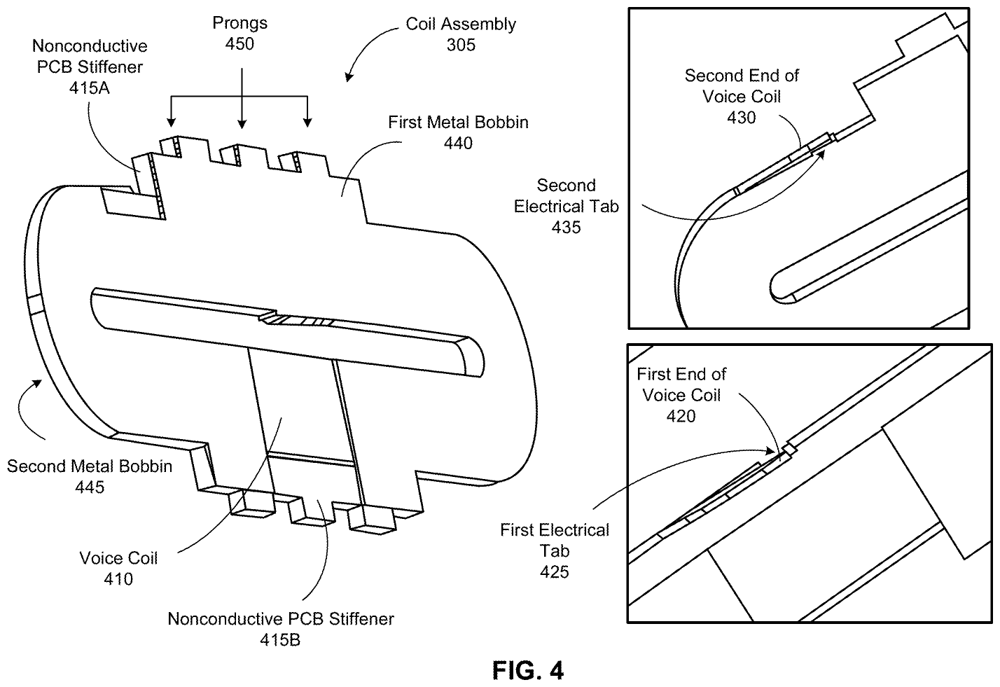

FIG. 4 illustrates perspective views of the coil assembly 305. The coil assembly 305 includes a voice coil 410 (wire coil), a metal bobbin assembly, and one or more nonconductive PCB stiffeners (e.g., nonconductive PCB stiffener 415A and nonconductive PCB stiffener 415B).

The voice coil 410 is a winding of metal wire, configured to generate a magnetic field when current is applied to it. The voice coil has a first end 420 and a second end 430. The voice coil 410 may be made of copper or aluminum.

The metal bobbin assembly includes a first metal bobbin 440 and a second metal bobbin 445. The metal bobbin assembly may be configured to provide a reliable electrical pathway to the first end 420 and the second end 430 of the voice coil. The voice coil 410 may be positioned in between the first metal bobbin 440 and second metal bobbin 445. The first metal bobbin 440 and the second metal bobbin 445 are fabricated to include electrical tabs, configured to provide a reliable electrical contact point for the voice coil. This is illustrated by the close-up view of the first end 420 of the voice coil and the second end 430 of the voice coil. The first metal bobbin 440 may include a first electrical tab 425, configured to make contact with the first end of the voice coil. The second metal bobbin 445 may include a second electrical tab 435, configured to make contact with the second end of the voice coil. The first and second electrical tab may be treated, such as tin dipped or plated, to provide increased solderability in the connection area.

The nonconductive PCB stiffeners 415A, 415B may be positioned in between the first metal bobbin 440 and second metal bobbin 445. The nonconductive PCB stiffeners 415A, 415B are configured to provide support between the metal bobbins and prevent the first metal bobbin 440 and second bobbin from shorting. The nonconductive PCB stiffeners 415A, 415B may be shaped according to the prongs 450 of the metal bobbin assembly. The nonconductive PCB stiffeners 415A, 415B may be positioned along the long sides of the voice coil and aligned with the prongs of the metal bobbin assembly.

The metal bobbin assembly may be coupled to the spring 315 via prongs 450 extruding from a first end of the first metal bobbin 440 and a first end of the second metal bobbin 445.

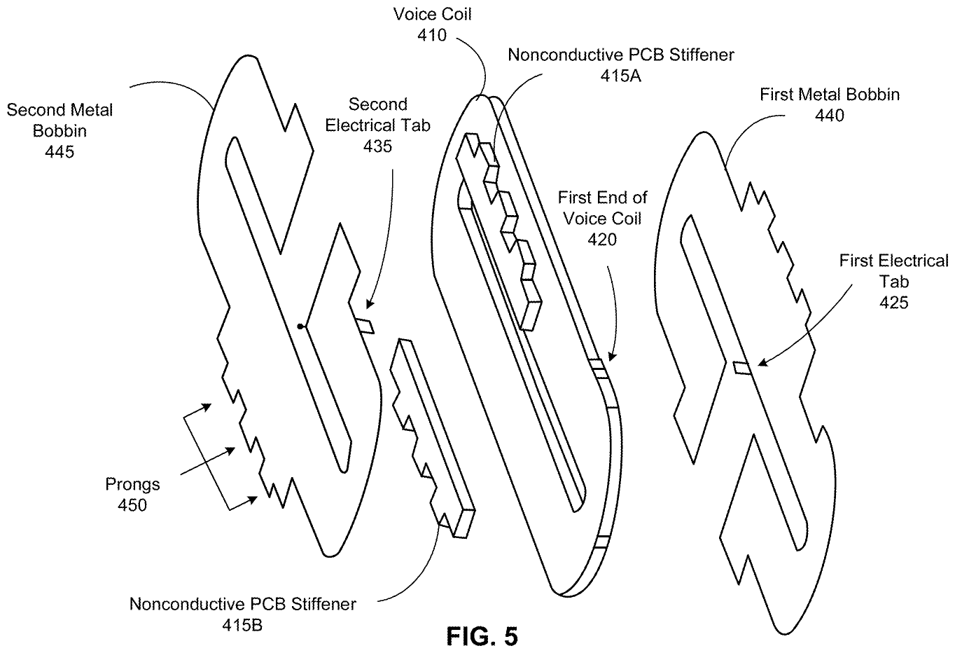

FIG. 5 is an exploded view of the coil assembly 305. As described in FIG. 4, the voice coil 410 is positioned between the first metal bobbin 440 and second metal bobbin 445. The first and second metal bobbins each have a first face and a second face. The first face of the first metal bobbin 440 faces the voice coil 410. The first electrical tab 425 is positioned at a 0 to 180-degree angle with respect to the first face of the first metal bobbin 440. Likewise, the first face of the second metal bobbin 445 faces the voice coil 410. The second electrical tab 435 is positioned at a 0 to 180-degree angle with respect to the first face of the second metal bobbin 445. In addition, the first face of the first metal bobbin 440 and the first face of the second metal bobbin 445 is anodized to prevent shorting between the metal bobbin assembly and the voice coil 410.

### Method for Generating Micro Noises for a Virtual Environment

Some embodiments of the present disclosure are directed to a method for generating micro noises for improving simulated presence. Micro noises are faint sounds that indicate presence. Micro noises may include, e.g., breathing, cloth rustling, sounds of movement, clicking, etc. For example, if the state indicates that the entity is present, the audio controller 230 may generate a plurality of micro noises to, e.g., simulate breathing, cloth rustling, movement, etc., which help cue the user that the entity is present. In other embodiments, the virtual avatars may be represented as a hologram.

FIG. 6 is an example virtual environment 615 displayed to a user by a headset, in accordance with one or more embodiments. Users may interact with virtual objects in the virtual environment 615. For example, users may use artificial reality devices that allow a user to view and interact with a virtual object in an artificial reality environment. In some embodiments a virtual avatar 620A and a virtual avatar 620B (collectively referred to as virtual avatars 620) are a virtual representation of respective entities in the virtual environment 615. An entity may be a user or an artificial intelligence. A virtual avatar may present as a 3D rendered image of a person (e.g., the person backing the virtual avatar), some other virtual object, etc.

A device 605 is associated with the virtual avatar 620A and includes a state 625 of the virtual avatar 620A. The device 605 may be a headset of another user or a server. A user uses a device 610 (e.g., headset) to enter the virtual environment 615 and is represented by virtual avatar 620B. The state 625 of the virtual avatar 620A may indicate whether the virtual avatar 620A is available to interact with the user. For example, the state 625 may indicate that the entity represented by the virtual avatar 620A is off-line and not available, or that the entity represented by the virtual avatar 620A is on-line but not immediately available, or that the entity represented by the virtual avatar 620A is on-line and actively present in the virtual environment, etc. In some embodiments, an entity (e.g., AI or user) associated with the device 605 may set the state 625 of the associated virtual avatar 620A. In other embodiments, where the device 605 is a user's headset, the device 605 may be configured to set the state 625 of the virtual avatar 620A based in part on the activity of the user on the device 605. For example, the device 605 may detect that the user has been inactive for a certain amount of time and may set the status of the virtual avatar 620A to online, but not immediately available.

When the virtual avatar 620B of the user is within a threshold distance of virtual avatar 620A, the device 610 may detect that the virtual avatar 620A is close by and determine the state 625 of the virtual avatar 620A. The device 605 may transmit the state 625 of the virtual avatar 620A to a central server, from which the device 610 may request the state 625 of the virtual avatar 620A when virtual avatar 620B is in close proximity to virtual avatar 620A. The device 610 may generate a plurality of micro noises 630 based in part on the determined state 625 of the virtual avatar 620A and present the plurality of micro noises 630 to the user of device 610. The state 625 of the virtual avatar may be associated with one or more types of micro noises 630.

FIG. 7 is a flowchart illustrating an example process of generating micro noises, in accordance with one or more embodiments. The process 700 shown in FIG. 7 may be performed by components of an audio system 200 of a device (the headset 100, the device 610). Other entities may perform some or all of the steps in FIG. 7 in other embodiments. Various embodiments may include different and/or additional steps or perform the steps in different orders. FIG. 7 will be described below in conjunction with FIG. 6.

The device determines 705 a state of a virtual object. The state 625 of virtual avatar 620A may be transmitted to a central server that is accessible by other devices (e.g., device 610) that have access to the virtual environment 615. The device 610 may request from the central server the state 625 of virtual avatar 620A. In other embodiments, the state 625 of virtual avatar 620A may be broadcasted to virtual avatar 620B in the virtual environment 615.

The device is configured to generate 710 a plurality of micro noises 630 based in part on the determined state 625. In some embodiments, the micro noises 630 may be generated randomly. In other embodiments, the plurality of micro noises 630 is generated based on movement of the virtual avatar. For example, if the virtual avatar 620A is walking in the virtual environment, a micro noise that may be generated is the sound of footsteps. In another example, if the determined state 625 indicates that the entity is on-line, but not immediately available, the audio controller 230 of device 610 may generate the plurality of micro noises 630 to be high frequency clicks, hum, etc., that cue the user that there is a virtual avatar 620A at a particular location and that the entity behind the virtual avatar 620A is not presently available. As the micro noises 630 are generated at the receiving device (e.g., headset), there is low latency between detecting the virtual avatar 620A and the user hearing the micro noise through the transducer array 210. In some embodiments, the audio controller 230 is configured to use different types of micro noises 630 based on whether the entity operating the virtual avatar is a real person or an artificial intelligence. In other embodiments, a user may assign a micro noise to a particular virtual avatar. For example, a user may select and assign a micro noise to a virtual avatar associated with a friend or family member.

In some embodiments, the micro noise generation may be based in part on actual sounds recorded of the user. The audio controller 230 may build a body noise profile for the user by capturing sounds from the user using the sensor array 220, the sounds may include breathing sounds, rustling sounds, clothing moving sounds, and hair moving sounds. The audio controller 230 may synthesize, using the captured sounds, a plurality of micro noises 630 associated with the user. In some embodiments, the audio controller 230 may retrieve the recorded sounds from a social graph and use them to generate the plurality of micro noises 630. In other embodiments, the plurality of micro noises 630 is generated by some other device using the recorded sounds and uploaded to the social graph, and the audio controller 230 may download them for use.

The device is configured to spatialize 715 the plurality of micro noises, such that the plurality of micro noises appears to originate from the virtual avatar 620A. For example, if a virtual avatar is far away from the user's virtual avatar in the virtual environment, the volume of speech coming from the virtual avatar will be low. In this manner, micro noises (e.g., breathing, cloth movement, etc.) further add realism to the artificial reality experience. Moreover, in some embodiments, the micro noises 630 can be used to distinguish whether an entity controlling a virtual avatar is a real person or an artificial intelligence, a state 625 of the entity (e.g., present, not present, etc.), etc.

Speaker Diaphragm Motion Detection with Optical MEMS Sensors

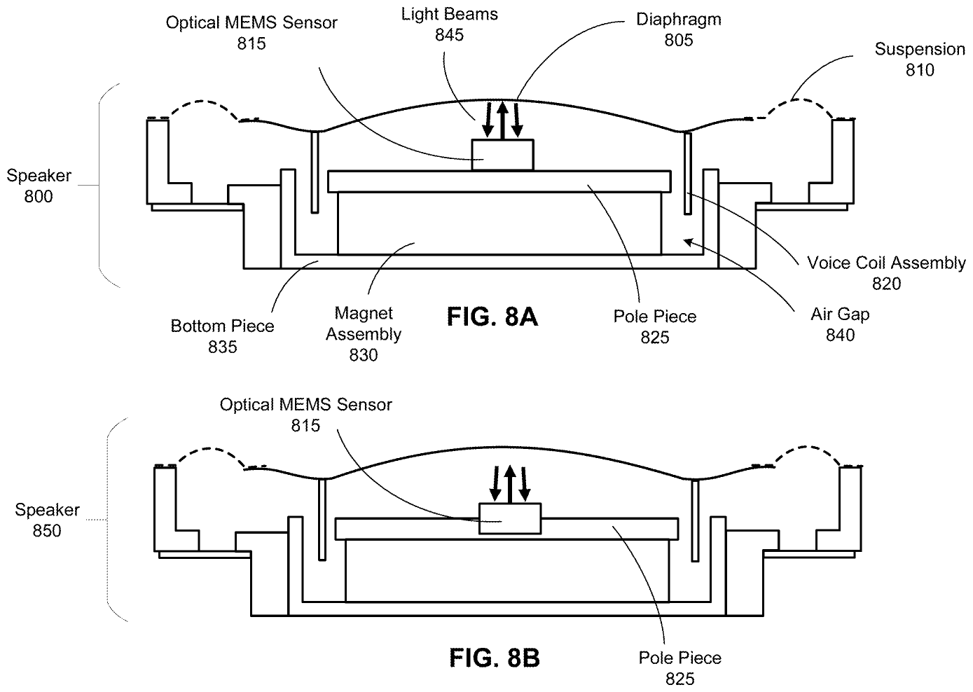

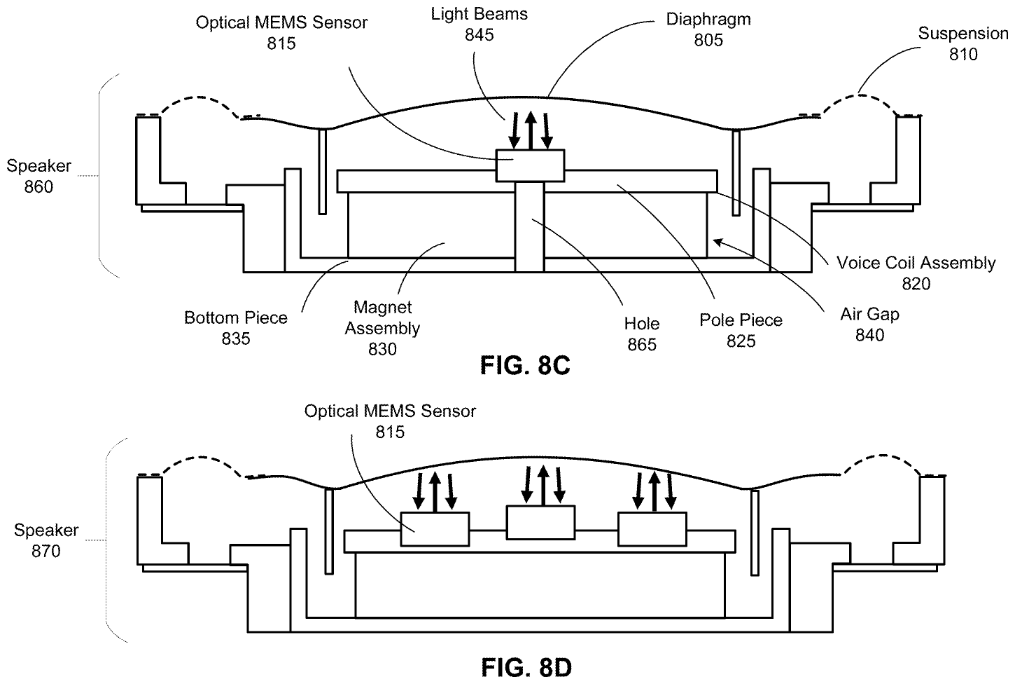

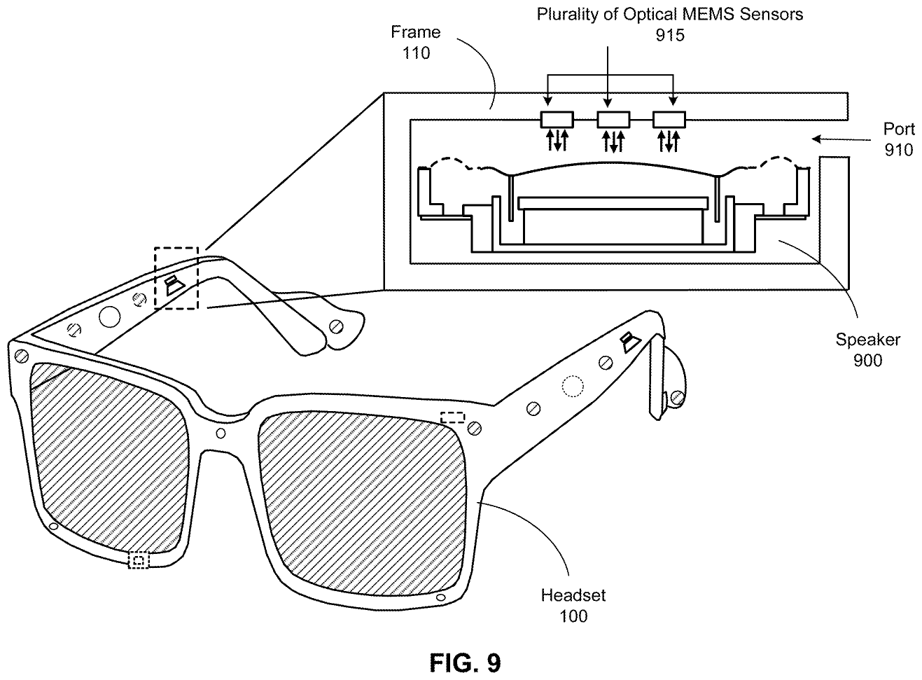

Some embodiments of the present disclosure are directed to a speaker that includes optical MEMS sensors for speaker diaphragm motion detection. FIG. 8A is a cross sectional view of an example structure of a speaker 800 with an optical MEMS sensor 815 located on a top surface of a pole piece 825 of a magnet assembly 830, in accordance with one or more embodiments. The speaker is an embodiment of the speaker 160. The speaker includes a diaphragm 805, suspension 810, an optical MEMS sensor 815, voice coil assembly 820, a pole piece 825, and a magnet assembly 830.

The diaphragm 805 is a thin, semi-rigid membrane which is configured to generate sound pressure waves when vibrated. The diaphragm 805 includes a front surface and a back surface. An end of the diaphragm 805 is coupled to a fixed structure using the suspension 810. The suspension 810 may also be referred to as a “surround”. The surround suspends the diaphragm 805 and is configured to flex and allow movement of the diaphragm 805. The suspension 810 couples the diaphragm 805 to a fixed structure. The fixed structure may be coupled to a structure, such as an enclosure that houses the speaker system.

The voice coil assembly 820 may include a metal wire (e.g., voice coil) wound tightly around a cylindrical structure (e.g., a former), and is configured to generate a magnetic field when current is applied to the voice coil. A base of the voice coil assembly 820 is coupled to the back surface of the diaphragm 805. In some embodiments, the voice coil assembly 820 is coupled to the end of the diaphragm 805 at a substantially close distance to the surround. The magnet assembly 830 is fitted on the center of the bottom piece 835 and is configured to generate a magnetic field. The space between the bottom piece and the magnet assembly 830 creates an air gap 840. The pole piece is placed over the magnet assembly 830 and is configured to direct the magnetic field generated by the magnet assembly 830 in the air gap 840.

The voice coil assembly 820 is positioned within the air gap 840 of the magnet assembly 830. During speaker operation, current is applied to the voice coil which generates a magnetic field. The magnetic field generated by the voice coil interacts with the magnetic field generated by the magnet, generating a magnetic force causing the voice coil assembly 820 to move in an up and down motion and an equal and opposite force causing the magnet assembly 830 to move in the opposite direction. The up and down movement of the voice coil assembly 820 causes the diaphragm 805 to vibrate, the front surface of the diaphragm 805 generating positive sound pressure waves that travel through the air from the front of the speaker system.

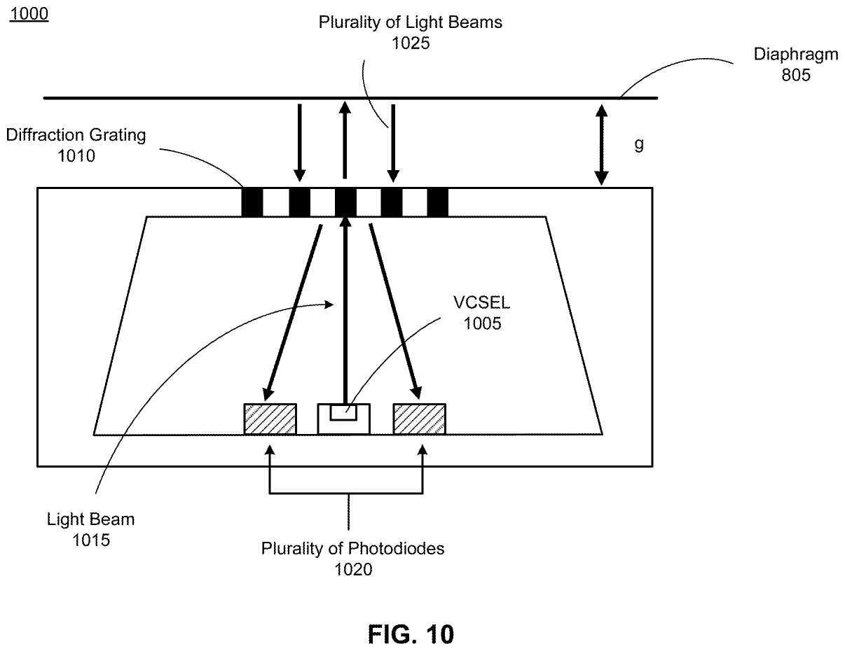

The optical MEMS sensor 815 is configured to optically monitor displacement of one or more portions of a diaphragm 805. The optical MEMS sensor 815 is positioned on top of the center of the pole piece 825. The optical MEMS sensor 815 is configured to emit light beams 845 towards the diaphragm 805 to detect the movement of the diaphragm 805 by monitoring the back surface of the diaphragm 805. The movement of the diaphragm 805 allows audio render algorithms more accurately identify system parameters and tune the algorithm optimally in real time. The operation of the optical MEMS sensor 815 will be further described in FIG. 10.

FIG. 8B is a cross sectional view of an example structure of a speaker 850 with an optical MEMS sensor recessed in a top surface of a pole piece, in accordance with one or more embodiments. The speaker 850 is an embodiment of the speaker 160. The optical MEMS sensor 815 may be recessed in the center of the top of the pole piece 825. This creates a larger gap between the diaphragm 805 and optical MEMS sensor 815.

FIG. 8C is a cross sectional view of an example structure of a speaker 860 with an optical MEMS sensor recessed in a top surface of a pole piece, in accordance with one or more embodiments. The speaker 860 is an embodiment of the speaker 160. A vertical hole 865 may be made through the center of the magnet assembly 830 and the pole piece 825, allowing more convenient assembly of the speaker and simplifying the process of connecting a power supply and readout circuitry to the optical MEMS sensor 815. In FIG. 8C, the optical MEMS sensor 815 may be recessed in the center of the top of the pole piece, over the vertical hole 865. Like the illustrated embodiment in FIG. 8B, recessing the optical MEMS sensor 815 in the pole piece 825 creates a larger gap between the diaphragm 805 and the optical MEMS sensor 815.

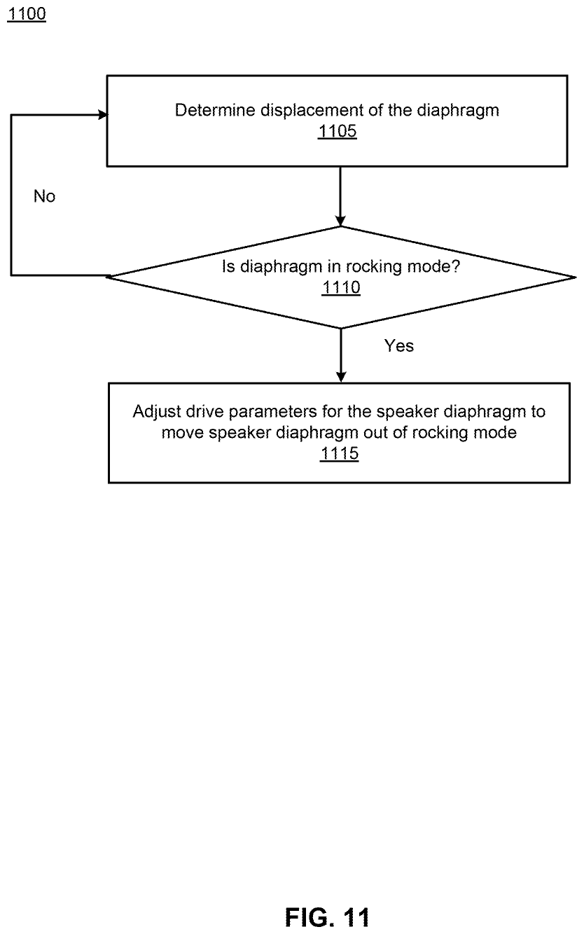

FIG. 8D is a cross sectional view of an example structure of a speaker 870 with a plurality of optical MEMS sensor recessed into a top surface of a pole piece, in accordance with one or more embodiments. The speaker 870 is an embodiment of the speaker 160. The plurality of optical MEMS sensors may be positioned on top of the pole piece 825. The plurality of optical MEMS sensors may be positioned substantially equidistant from each other, and in line with a central diameter of the pole piece 825. The plurality of MEMS sensors may enable multiple point motion detection and may be used for rocking mode detection. Rocking mode vibration has undesirable acoustic effects, such as loss of acoustic efficiency or distortion of the sound radiated by the passive radiator. Rocking mode vibration tends to occur at specific frequencies that are related to characteristics of the diaphragm 805, the suspension 810, and the acoustic enclosure, the placement and the mechanical and acoustic characteristics of the acoustic driver, and other factors. In some embodiments, the audio system may, e.g., monitor if the diaphragm 805 enters a rocking mode, and actively tune the diaphragm 805 to move out of the rocking mode (and potentially avoid the rocking mode in the future). Details regarding rocking mode detection will be further described in FIG. 11.

FIG. 9 is a cross sectional view of an example structure of a speaker 900 with a plurality of optical MEMS sensors 915 positioned in an enclosure of a wearable device, in accordance with one or more embodiments. The speaker 900 may be positioned inside of a headset where a frame 110 of the headset and the diaphragm 805 form a front volume of the speaker. In some embodiments, some or all of the plurality of optical MEMS sensors 915 may be recessed into the frame 110 to monitor a front side of the diaphragm 805. As such, the optical MEMS sensors 915 are separated from the speaker transducer and flexible for audio system integration designs. The headset 100 may include a port 910 on the frame 110 close to the speaker, allowing the headset to vent sound to the user.

FIG. 10 is a cross sectional view of an example structure of an optical MEMS sensor 1000, in accordance with one or more embodiments. The optical MEMS sensor 1000 is an embodiment of the optical MEMS sensor 815. The optical MEMS sensor 1000 may include one or more light sources (e.g., vertical cavity surface emitting lasers (VCSELs)), one or more sensors (e.g., photodiodes), and may also include one or more diffraction gratings. For example, in some embodiments, the optical MEMS sensor 1000 includes a VCSEL 1005, a diffraction grating 1010, and a plurality of photodiodes 1020. The VCSEL 1005 emits light beam 1015 through the diffraction grating 1010 which diffracts the light from the VCSEL 1005 into a plurality 1025 of light beams that are output toward the diaphragm 805. The plurality of beams reflects off the diaphragm 805, are diffracted by the diffraction grating 1010 and are detected by the plurality of photodiodes 1020. Some or all of the photodiodes 1020 are positioned within the optical MEMS sensor to monitor light from the VCSEL that reflected off a different portion of the diaphragm 805.

FIG. 11 is a flowchart illustrating a process of tuning the diaphragm to move out of rocking mode, in accordance with one or more embodiments. The process 1100 shown in FIG. 11 may be performed by components of the audio system 200. Other entities may perform some or all of the steps in FIG. 11 in other embodiments. Various embodiments may include different and/or additional steps or perform the steps in different orders.

The audio controller 230 is configured to determine 1105 displacement of a diaphragm based in part on optically monitored portions of the diaphragm. The audio controller 230 may instruct the plurality of optical MEMs sensors 815 to emit light beams towards the moving diaphragm 805 to monitor the movement of the diaphragm 805. The audio controller 230 may receive signals from the plurality of optical MEMS sensors 815 associated to the movement of the diaphragm 805. The audio controller 230 may provide the received signals as input into a depth determination technique like, e.g., direct time-of-flight (dTOF), indirect TOF (iTOF), etc., to calculate the displacement of monitored portions of the diaphragm 805. In some embodiments, the headset may also extrapolate displacement of the entire diaphragm 805 using the calculated displacement of some or all of the monitored portions of the diaphragm 805.

The audio controller 230 is configured to determine 1110 whether the diaphragm 805 is in a rocking mode using the calculated displacement. Normally, the diaphragm 805 moves up and down as a piston so the displacement at different locations is equal to each. In addition, considering the stiffness of the surround, the center of the diaphragm 805 may have larger displacement than the other points, the closer to the surround, the smaller displacement. However, it is monotonous along the radial direction. In rocking mode, however, the displacement is no longer monotonous in radial direction, which means two symmetrical points have opposite displacement, one moving upwards and the other downwards. If this happens, the displacement calculation can capture the rocking mode using data from at least two optical MEMs sensors.

In response to the audio controller 230 determining that the speaker is in or close to being in a rocking mode, the audio controller 230 is configured to adjust 1115 drive algorithm parameters for the diaphragm 805 to move the diaphragm 805 out of the rocking mode. The audio controller 230 may provide the adjusted drive algorithm parameters to the transducer. In contrast, if the audio controller 230 determines that the speaker is not in rocking mode, the speaker will continue determining 1105 the displacement of the diaphragm 805 to ensure that the diaphragm 805 is not in rocking mode.

FIG. 12 is a system 1200 that includes a headset 1205, in accordance with one or more embodiments. In some embodiments, the headset 1205 may be the headset 100 of FIG. 1A or the headset 105 of FIG. 1B. The system 1200 may operate in an artificial reality environment (e.g., a virtual reality environment, an augmented reality environment, a mixed reality environment, or some combination thereof). The system 1200 shown by FIG. 12 includes the headset 1205, an input/output (I/O) interface 1210 that is coupled to a console 1215, the network 1220, and the mapping server 1225. While FIG. 12 shows an example system 1200 including one headset 1205 and one I/O interface 1210, in other embodiments any number of these components may be included in the system 1200. For example, there may be multiple headsets each having an associated I/O interface 1210, with each headset and I/O interface 1210 communicating with the console 1215. In alternative configurations, different and/or additional components may be included in the system 1200. Additionally, functionality described in conjunction with one or more of the components shown in FIG. 12 may be distributed among the components in a different manner than described in conjunction with FIG. 12 in some embodiments. For example, some or all of the functionality of the console 1215 may be provided by the headset 1205.

The headset 1205 includes the display assembly 1230, an optics block 1235, one or more position sensors 1240, and the DCA 1245. Some embodiments of headset 1205 have different components than those described in conjunction with FIG. 12. Additionally, the functionality provided by various components described in conjunction with FIG. 12 may be differently distributed among the components of the headset 1205 in other embodiments, or be captured in separate assemblies remote from the headset 1205.

The display assembly 1230 displays content to the user in accordance with data received from the console 1215. The display assembly 1230 displays the content using one or more display elements (e.g., the display elements 120). A display element may be, e.g., an electronic display. In various embodiments, the display assembly 1230 comprises a single display element or multiple display elements (e.g., a display for each eye of a user). Examples of an electronic display include: a liquid crystal display (LCD), an organic light emitting diode (OLED) display, an active-matrix organic light-emitting diode display (AMOLED), a waveguide display, some other display, or some combination thereof. Note in some embodiments, the display element 120 may also include some or all of the functionality of the optics block 1235.

The optics block 1235 may magnify image light received from the electronic display, corrects optical errors associated with the image light, and presents the corrected image light to one or both eyeboxes of the headset 1205. In various embodiments, the optics block 1235 includes one or more optical elements. Example optical elements included in the optics block 1235 include: an aperture, a Fresnel lens, a convex lens, a concave lens, a filter, a reflecting surface, or any other suitable optical element that affects image light. Moreover, the optics block 1235 may include combinations of different optical elements. In some embodiments, one or more of the optical elements in the optics block 1235 may have one or more coatings, such as partially reflective or anti-reflective coatings.

Magnification and focusing of the image light by the optics block 1235 allows the electronic display to be physically smaller, weigh less, and consume less power than larger displays. Additionally, magnification may increase the field of view of the content presented by the electronic display. For example, the field of view of the displayed content is such that the displayed content is presented using almost all (e.g., approximately 110 degrees diagonal), and in some cases, all of the user's field of view. Additionally, in some embodiments, the amount of magnification may be adjusted by adding or removing optical elements.

In some embodiments, the optics block 1235 may be designed to correct one or more types of optical error. Examples of optical error include barrel or pincushion distortion, longitudinal chromatic aberrations, or transverse chromatic aberrations. Other types of optical errors may further include spherical aberrations, chromatic aberrations, or errors due to the lens field curvature, astigmatisms, or any other type of optical error. In some embodiments, content provided to the electronic display for display is pre-distorted, and the optics block 1235 corrects the distortion when it receives image light from the electronic display generated based on the content.

The position sensor 1240 is an electronic device that generates data indicating a position of the headset 1205. The position sensor 1240 generates one or more measurement signals in response to motion of the headset 1205. The position sensor 190 is an embodiment of the position sensor 1240. Examples of a position sensor 1240 include: one or more IMUs, one or more accelerometers, one or more gyroscopes, one or more magnetometers, another suitable type of sensor that detects motion, or some combination thereof. The position sensor 1240 may include multiple accelerometers to measure translational motion (forward/back, up/down, left/right) and multiple gyroscopes to measure rotational motion (e.g., pitch, yaw, roll). In some embodiments, an IMU rapidly samples the measurement signals and calculates the estimated position of the headset 1205 from the sampled data. For example, the IMU integrates the measurement signals received from the accelerometers over time to estimate a velocity vector and integrates the velocity vector over time to determine an estimated position of a reference point on the headset 1205. The reference point is a point that may be used to describe the position of the headset 1205. While the reference point may generally be defined as a point in space, however, in practice the reference point is defined as a point within the headset 1205.

The DCA 1245 generates depth information for a portion of the local area. The DCA includes one or more imaging devices and a DCA controller. The DCA 1245 may also include an illuminator. Operation and structure of the DCA 1245 is described above with regard to FIG. 1A.

The audio system 1250 provides audio content to a user of the headset 1205. The audio system 1250 is substantially the same as the audio system 200 describe above. The audio system 1250 may comprise one or acoustic sensors, one or more transducers, and an audio controller. In some embodiments, the one or more transducers may be implemented with a coil assembly 305, the coil assembly 305 may be configured to act as an electrical pathway between a voice coil and an electrical source. The coil assembly may include a metal bobbin assembly, a voice coil, and one or more nonconductive PCB stiffeners. In other embodiments, the one or more transducers may be implemented with an optical MEMS sensor that may be configured to monitor the movement of a diaphragm of a speaker. In some embodiments, the one or more transducers may be implemented with more than one optical MEMS sensors, which allow the audio system 1250 to determine whether the diaphragm is in rocking mode.

The audio controller may include a micro noise generator module that generates micro noises based in part on a determined state of a virtual object in a virtual environment. In some embodiments, the micro noise generator module may generate a plurality of micro noises based in part on a nature of the virtual object or an action performed by the virtual object. The audio system 1250 may apply sound filters to the plurality of micro noises to spatialize the micro noise, such that the plurality of micro noises appear to originate from the virtual object.

The audio controller may include a speaker tuning module 295 that is configured to determine if the diaphragm is in rocking mode and to tune speaker algorithm parameters to move the diaphragm out of rocking mode. The speaker tuning module 295 may use signals received from a speaker including more than one optical MEMS sensors to determine whether the diaphragm is in rocking mode.

In some embodiments, the audio system 1250 may request acoustic parameters from the mapping server 1225 over the network 1220. The acoustic parameters describe one or more acoustic properties (e.g., room impulse response, a reverberation time, a reverberation level, etc.) of the local area. The audio system 1250 may provide information describing at least a portion of the local area from e.g., the DCA 1245 and/or location information for the headset 1205 from the position sensor 1240. The audio system 1250 may generate one or more sound filters using one or more of the acoustic parameters received from the mapping server 1225, and use the sound filters to provide audio content to the user.

The I/O interface 1210 is a device that allows a user to send action requests and receive responses from the console 1215. An action request is a request to perform a particular action. For example, an action request may be an instruction to start or end capture of image or video data, or an instruction to perform a particular action within an application. The I/O interface 1210 may include one or more input devices. Example input devices include: a keyboard, a mouse, a game controller, or any other suitable device for receiving action requests and communicating the action requests to the console 1215. An action request received by the I/O interface 1210 is communicated to the console 1215, which performs an action corresponding to the action request. In some embodiments, the I/O interface 1210 includes an IMU that captures calibration data indicating an estimated position of the I/O interface 1210 relative to an initial position of the I/O interface 1210. In some embodiments, the I/O interface 1210 may provide haptic feedback to the user in accordance with instructions received from the console 1215. For example, haptic feedback is provided when an action request is received, or the console 1215 communicates instructions to the I/O interface 1210 causing the I/O interface 1210 to generate haptic feedback when the console 1215 performs an action.

The console 1215 provides content to the headset 1205 for processing in accordance with information received from one or more of: the DCA 1245, the headset 1205, and the I/O interface 1210. In the example shown in FIG. 12, the console 1215 includes an application store 1255, a tracking module 1260, and an engine 1265. Some embodiments of the console 1215 have different modules or components than those described in conjunction with FIG. 12. Similarly, the functions further described below may be distributed among components of the console 1215 in a different manner than described in conjunction with FIG. 12. In some embodiments, the functionality discussed herein with respect to the console 1215 may be implemented in the headset 1205, or a remote system.

The application store 1255 stores one or more applications for execution by the console 1215. An application is a group of instructions, that when executed by a processor, generates content for presentation to the user. Content generated by an application may be in response to inputs received from the user via movement of the headset 1205 or the I/O interface 1210. Examples of applications include: gaming applications, conferencing applications, video playback applications, or other suitable applications.

The tracking module 1260 tracks movements of the headset 1205 or of the I/O interface 1210 using information from the DCA 1245, the one or more position sensors 1240, or some combination thereof. For example, the tracking module 1260 determines a position of a reference point of the headset 1205 in a mapping of a local area based on information from the headset 1205. The tracking module 1260 may also determine positions of an object or virtual object. Additionally, in some embodiments, the tracking module 1260 may use portions of data indicating a position of the headset 1205 from the position sensor 1240 as well as representations of the local area from the DCA 1245 to predict a future location of the headset 1205. The tracking module 1260 provides the estimated or predicted future position of the headset 1205 or the I/O interface 1210 to the engine 1265.

The engine 1265 executes applications and receives position information, acceleration information, velocity information, predicted future positions, or some combination thereof, of the headset 1205 from the tracking module 1260. Based on the received information, the engine 1265 determines content to provide to the headset 1205 for presentation to the user. For example, if the received information indicates that the user has looked to the left, the engine 1265 generates content for the headset 1205 that mirrors the user's movement in a virtual local area or in a local area augmenting the local area with additional content. Additionally, the engine 1265 performs an action within an application executing on the console 1215 in response to an action request received from the I/O interface 1210 and provides feedback to the user that the action was performed. The provided feedback may be visual or audible feedback via the headset 1205 or haptic feedback via the I/O interface 1210.

The network 1220 couples the headset 1205 and/or the console 1215 to the mapping server 1225. The network 1220 may include any combination of local area and/or wide area networks using both wireless and/or wired communication systems. For example, the network 1220 may include the Internet, as well as mobile telephone networks. In one embodiment, the network 1220 uses standard communications technologies and/or protocols. Hence, the network 1220 may include links using technologies such as Ethernet, 802.11, worldwide interoperability for microwave access (WiMAX), 2G/3G/4G mobile communications protocols, digital subscriber line (DSL), asynchronous transfer mode (ATM), InfiniBand, PCI Express Advanced Switching, etc. Similarly, the networking protocols used on the network 1220 can include multiprotocol label switching (MPLS), the transmission control protocol/Internet protocol (TCP/IP), the User Datagram Protocol (UDP), the hypertext transport protocol (HTTP), the simple mail transfer protocol (SMTP), the file transfer protocol (FTP), etc. The data exchanged over the network 1220 can be represented using technologies and/or formats including image data in binary form (e.g. Portable Network Graphics (PNG)), hypertext markup language (HTML), extensible markup language (XML), etc. In addition, all or some of links can be encrypted using conventional encryption technologies such as secure sockets layer (SSL), transport layer security (TLS), virtual private networks (VPNs), Internet Protocol security (IPsec), etc.

The mapping server 1225 may include a database that stores a virtual model describing a plurality of spaces, wherein one location in the virtual model corresponds to a current configuration of a local area of the headset 1205. The mapping server 1225 receives, from the headset 1205 via the network 1220, information describing at least a portion of the local area and/or location information for the local area. The user may adjust privacy settings to allow or prevent the headset 1205 from transmitting information to the mapping server 1225. The mapping server 1225 determines, based on the received information and/or location information, a location in the virtual model that is associated with the local area of the headset 1205. The mapping server 1225 determines (e.g., retrieves) one or more acoustic parameters associated with the local area, based in part on the determined location in the virtual model and any acoustic parameters associated with the determined location. The mapping server 1225 may transmit the location of the local area and any values of acoustic parameters associated with the local area to the headset 1205.

One or more components of system 1200 may contain a privacy module that stores one or more privacy settings for user data elements. The user data elements describe the user or the headset 1205. For example, the user data elements may describe a physical characteristic of the user, an action performed by the user, a location of the user of the headset 1205, a location of the headset 1205, an HRTF for the user, etc. Privacy settings (or “access settings”) for a user data element may be stored in any suitable manner, such as, for example, in association with the user data element, in an index on an authorization server, in another suitable manner, or any suitable combination thereof.

A privacy setting for a user data element specifies how the user data element (or particular information associated with the user data element) can be accessed, stored, or otherwise used (e.g., viewed, shared, modified, copied, executed, surfaced, or identified). In some embodiments, the privacy settings for a user data element may specify a “blocked list” of entities that may not access certain information associated with the user data element. The privacy settings associated with the user data element may specify any suitable granularity of permitted access or denial of access. For example, some entities may have permission to see that a specific user data element exists, some entities may have permission to view the content of the specific user data element, and some entities may have permission to modify the specific user data element. The privacy settings may allow the user to allow other entities to access or store user data elements for a finite period of time.

The privacy settings may allow a user to specify one or more geographic locations from which user data elements can be accessed. Access or denial of access to the user data elements may depend on the geographic location of an entity who is attempting to access the user data elements. For example, the user may allow access to a user data element and specify that the user data element is accessible to an entity only while the user is in a particular location. If the user leaves the particular location, the user data element may no longer be accessible to the entity. As another example, the user may specify that a user data element is accessible only to entities within a threshold distance from the user, such as another user of a headset within the same local area as the user. If the user subsequently changes location, the entity with access to the user data element may lose access, while a new group of entities may gain access as they come within the threshold distance of the user.

The system 1200 may include one or more authorization/privacy servers for enforcing privacy settings. A request from an entity for a particular user data element may identify the entity associated with the request and the user data element may be sent only to the entity if the authorization server determines that the entity is authorized to access the user data element based on the privacy settings associated with the user data element. If the requesting entity is not authorized to access the user data element, the authorization server may prevent the requested user data element from being retrieved or may prevent the requested user data element from being sent to the entity. Although this disclosure describes enforcing privacy settings in a particular manner, this disclosure contemplates enforcing privacy settings in any suitable manner.

### Additional Configuration Information

The foregoing description of the embodiments has been presented for illustration; it is not intended to be exhaustive or to limit the patent rights to the precise forms disclosed. Persons skilled in the relevant art can appreciate that many modifications and variations are possible considering the above disclosure.

Some portions of this description describe the embodiments in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all the steps, operations, or processes described.

Embodiments may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments may also relate to a product that is produced by a computing process described herein. Such a product may comprise information resulting from a computing process, where the information is stored on a non-transitory, tangible computer readable storage medium and may include any embodiment of a computer program product or other data combination described herein.

Finally, the language used in the specification has been principally selected for readability and instructional purposes, and it may not have been selected to delineate or circumscribe the patent rights. It is therefore intended that the scope of the patent rights be limited not by this detailed description, but rather by any claims that issue on an application based hereon. Accordingly, the disclosure of the embodiments is intended to be illustrative, but not limiting, of the scope of the patent rights, which is set forth in the following claims.

What is claimed is:

1. A coil assembly comprising:
a metal bobbin assembly, the metal bobbin assembly comprising a first metal bobbin and a second metal bobbin;
a wire coil that is positioned between the first metal bobbin and the second metal bobbin, configured to generate a magnetic field; and
a nonconductive stiffener that is positioned between a portion of the first metal bobbin and the second metal bobbin, the nonconductive stiffener configured to prevent shorting between the first metal bobbin and the second metal bobbin,
wherein the bobbin assembly is configured to create an electrical pathway between the wire coil and an electrical source.

2. The coil assembly of claim 1, wherein the first metal bobbin further comprises a first face and a second face, the first face facing the wire coil and is anodized.

3. The coil assembly of claim 2, wherein the first metal bobbin further comprises a first electrical tab, the first electrical tab making an angle of 0 degrees to 180 degrees with respect to the first face of the first metal bobbin, the first electrical tab configured to make contact with a first end of the wire coil.

4. The coil assembly of claim 1, wherein the second metal bobbin further comprises a first face and a second face, the first face facing the wire coil and is anodized.

5. The coil assembly of claim 4, wherein the second metal bobbin comprises a second electrical tab, the second electrical tab making an angle of 0 degrees to 180 degrees with respect to the first face of the second metal bobbin, the second electrical tab configured to make contact with a second end of the wire coil.

6. The coil assembly of claim 5, wherein the first electrical tab and the second electrical tab are treated with metal plating.

7. A method, comprising:
determining a state of a virtual object, the state indicating whether the virtual object is available to interact with a user;
generating a plurality of micro noises based in part on the determined state; and
spatializing the plurality of micro noises, such that the plurality of micro noises appear to originate from the virtual object.

8. The method of claim 7, wherein the micro noises are generated on a user's device.

9. The method of claim 7, wherein virtual objects are assigned different micro noises, based in part on a type of the virtual object.

10. The method of claim 7, further comprising:
capturing noises made by the user;
generating, using the captured noises made by the user, one or more micro noises unique to the user; and
generating a presence audio profile for the user using the one or more generated micro noises.

11. The method of claim 10, wherein the plurality of generated micro noises matches a movement of the virtual object.

12. A speaker comprising:
an optical micro-electromechanical systems (MEMS) sensor, the optical MEMS sensor configured to optically monitor a portion of a speaker diaphragm; and
a controller configured to:
determine displacement of the speaker diaphragm based in part on the optically monitored portions of the speaker diaphragm;
determine that the speaker diaphragm is in a rocking mode using the determined displacement; and
adjust drive parameters for the speaker diaphragm to move the speaker diaphragm out of the rocking mode.

13. The speaker of claim 12, wherein the controller is further configured to perform an action selected from a group of actions comprising:
use the determined displacement as a feedback signal for identification of speaker system parameters; and
use the determined displacement for direction control.

14. The speaker of claim 12, wherein the optical MEMS sensor further comprises:
a light source, configured to emit light;
a diffraction grating, configured to diffract light from the light source into a plurality of beams, the plurality of beams directed toward the speaker diaphragm; and
a light sensor, configured to detect the diffracted light beams.

15. The speaker of claim 14, wherein the light sensor is positioned adjacent to the light source and below the diffraction grating.

16. The speaker of claim 14, further comprising:
a plurality of optical MEMs sensors, recessed into a top of a pole piece, positioned under a speaker diaphragm.

17. The speaker of claim 14, further comprising:
a plurality of optical MEMs sensors, positioned on a frame of a headset, above the speaker diaphragm.

18. The speaker of claim 14, the controller further configured to:
instruct a light source to emit a light beam toward the speaker diaphragm.

19. The speaker of claim 12, the controller further configured to:
apply a depth determination technique to determine the displacement of the speaker diaphragm.

20. The speaker of claim 12, the controller further configured to:
identifying two symmetrical points on the speaker diaphragm; and
determining that the two symmetrical points have opposite displacement.
